(19) United States
(12) Patent Application Publication
(10) Pub. No.: US 2008/0048290 A1
(43) Pub. Date: Feb. 28, 2008

(54) SEMICONDUCTOR DEVICE AND FABRICATING METHOD

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/841,082

(22) Filed: Aug. 20, 2007

(30) Foreign Application Priority Data
Aug. 23, 2006 (KR) 10-2006-0080120

(51) Int. Cl. H01L 29/00; H01L 21/02

(52) U.S. Cl. 257/532; 438/393; 257/E29.001; 257/E21.002

(57) ABSTRACT

A semiconductor device and a relatively simple fabrication process which may maximize fabrication yield. A semiconductor device may include at least one of the following: A first substrate including a capacitor cell. A second substrate including a circuit unit having a transistor and a wire. A connection electrode which electrically connects the capacitor cell and the circuit unit.

The present application claims priority under 35 U.S.C. 119 to Korean Patent Application No. 10-2006-0080120 (filed on Aug. 23, 2006), which is hereby incorporated by reference in its entirety.

### BACKGROUND

Capacitors may be implemented in relatively highly integrated semiconductor devices. Capacitors in semiconductor devices may have structures, such as a polysilicon to polysilicon structure, a polysilicon to silicon structure, a metal to silicon structure, a metal to polysilicon structure, a metal to metal structure, and other similar structures. Since metal to metal and metal/insulator/metal (MIM) structures in capacitors may have a relatively low series resistance, a capacitor may be fabricated to have a relatively high storage capacitor.

### SUMMARY

Embodiments relate to a semiconductor device and a relatively simple fabrication process which may maximize fabrication yield. In embodiments, a semiconductor device may include at least one of the following: A first substrate including a capacitor cell. A second substrate including a circuit unit having a transistor and a wire. A connection electrode which electrically connects the capacitor cell and the circuit unit.

In embodiments, a method of fabricating a semiconductor device may include at least one of the following: Forming a first substrate having a capacitor cell. Forming a second substrate having a circuit unit with a transistor and a wire. Stacking the first substrate on the second substrate. Electrically connecting the capacitor cell to the circuit unit.

### DRAWINGS

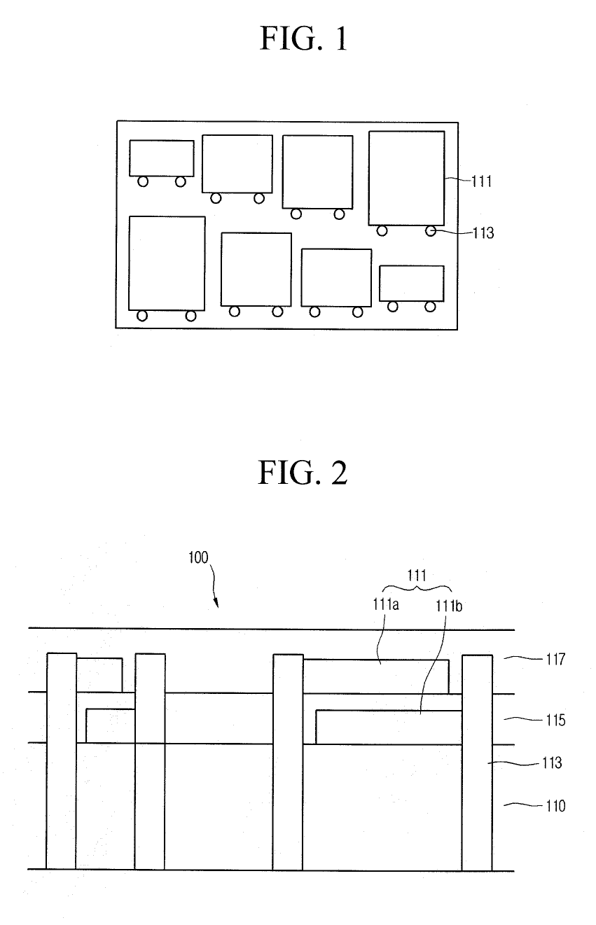

Example FIGS. 1 and 2 illustrate a substrate having capacitor cells, in accordance with embodiments.

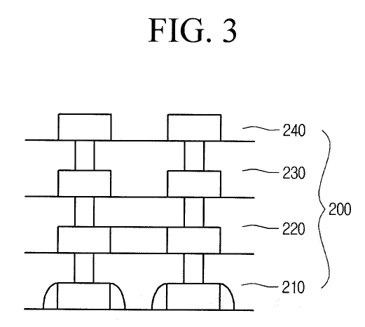

Example FIG. 3 illustrates a substrate having a circuit unit, according to embodiments.

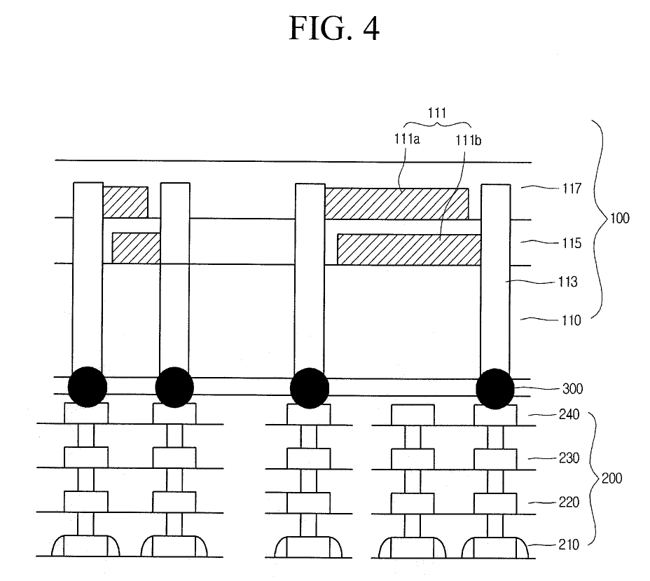

Example FIG. 4 illustrates a semiconductor device having a capacitor, in accordance with embodiments.

### DESCRIPTION

Embodiments relates to a method of effectively fabricating a semiconductor device having a capacitor by stacking a first substrate and a second substrate. A first substrate may have capacitor cells. A second substrate may have a circuit unit. In embodiments, first substrate and second substrate may be fabricated separately. A capacitor cell formed on the first substrate may be electrically connected to the circuit unit formed on the second substrate through a connection electrode. A capacitor cell may be an area where a top electrode and a bottom electrode of a capacitor are formed. In a capacitor cell, a stacking layer may be formed in the form of a top electrode/an insulation layer/a bottom electrode.

Example FIG. 1 illustrates a substrate having capacitor cells, according to embodiments. Example FIG. 2 is a cross-sectional view of a substrate having capacitor cells, according to embodiments. First substrate 100 may include capacitor cell 111 and penetration electrode 113. Capacitor cell 111 may includes top electrode 111a and bottom electrode 111b. Penetration electrode 113 may connect top electrode 111a and bottom electrode 111b of capacitor cell 111. One of ordinary skill in the art appreciates different locations and/or orientations of penetration electrode, in accordance with embodiments.

In embodiments, first substrate 100 may be fabricated by forming bottom electrode 111b on and/or over semiconductor substrate 110. Insulation layer 115 may be formed on and/or over bottom electrode 111b. Top electrode 111a may be formed on and/or over insulation layer 115. In embodiments, at least one insulation layer may be formed between semiconductor substrate 110 and bottom electrode 111b.

Penetration electrode 113 may be formed through semiconductor substrate 110. Penetration electrode 113 may be connected to capacitor cell 111. Penetration electrode 113 may be formed by performing patterning process, an etching process, a metal forming process, and/or a CMP process on semiconductor substrate 110. Those skilled in the art appreciate modifications and method of forming penetration electrode 113, in accordance with embodiments.

Top electrode 111a may include at least one of W, Cu, Al, Ag, and Au, in accordance with embodiments. Bottom electrode 111b may include at least one of W, Cu, Al, Ag, and Au, in accordance with embodiments. Penetration electrode 113 may include at least one of W, Cu, Al, Ag, and Au, in accordance with embodiments. Capacitor cell 111 and/or penetration electrode 113 may be deposited through at least one of chemical vapor deposition (CVD), physical vapor deposition (PVD), an Evaporation process, electrochemical planting (ECP) process, or other similar process. In embodiments, at least one of capacitor cell 111 and penetration electrode 113 may include a barrier metal layer. In embodiments, a barrier metal layer may include at least one of TaN, Ta, TiN, Ti, TiSiN, or similar material. A barrier metal layer may be formed by CVD, PVD, atomic layer deposition (ALD), or other similar process, in accordance with embodiments. In embodiments, passivation layer 117 may be formed over capacitor cell 111.

Example FIG. 3 illustrates a substrate including a circuit unit, according to embodiments. In embodiments, second substrate 500 may include at least one of transistor layer 210, first metal layer 220, second metal layer 230, and third metal layer 240. One of ordinary skill would appreciate any number of metal layers and/or different configurations of transistor layer 210, in accordance with embodiments.

Transistor layer 210 and metal layers (e.g. first metal layer 220, second metal layer 230, and third metal layer 240) may form a circuit unit, which may process signals. Although FIG. 3 shows three metal layers, one of ordinary skill would appreciate any number of metal layers formed on and/or over second substrate 200, in accordance with embodiments.

As illustrated in example FIG. 4, first substrate 100 and second substrate 200 may be stacked, in accordance with embodiments. A semiconductor device may include a capacitor included in a first substrate 100 electrically connected to a second substrate 200 through connection electrode 300, in accordance with embodiments. Connection electrode 300 may connect capacitor cell 111 in first substrate 100 a circuit unit 200 in second substrate 200, in accordance with embodiments. Connection electrode 300 may electrically connect capacitor cell 111 through penetration electrode 113 formed in first substrate 100. Connection electrode 300 may connect a top electrode in third metal layer 240 of a circuit unit. In embodiments, at least one of an electrode of a capacitor cell and a penetration electrode may include at least one of W, Cu, Al, Ag, Au, or similar material.

In embodiments, a semiconductor device may include a capacitor in a system in a package (SiP) semiconductor device. In embodiments, since a first substrate including a capacitor cell and a second substrate including a transistor and a metal wire are manufactured independently, yield may be improved as it is not necessary to discard an entire device if one of the first substrate and the second substrate are defective. For example, if the first substrate is defective and the second substrate is not defective, then it is not necessary to discard the second substrate.

In embodiments, it may be more easy and/or cost effective for a manufacturer to have a library of capacitors by mixing and matching different configurations of first substrate and second substrate. In embodiments, unintended influence (e.g. from semiconductor manufacturing processes) from a capacitor on a circuit unit may be minimized since a capacitor is in a first substrate and a circuit unit is in a second substrate. Accordingly, a semiconductor device and a fabricating method may have a relatively simple fabricating processes and/or maximized fabrication yield, in accordance with embodiments.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first substrate comprising a capacitor cell;
a second substrate comprising a circuit unit, wherein the circuit unit comprises at least one transistor and at least one wire; and
a connection electrode which electrically connects the capacitor cell and the circuit unit.

2. The apparatus of claim 1, wherein the first substrate comprises a penetration electrode connected to the capacitor cell, wherein the penetration electrode penetrates the semiconductor substrate.

3. The apparatus of claim 2, wherein the penetration electrode comprises at least one of W, Cu, Al, Au, and Au.

4. The apparatus of claim 2, wherein the connection electrode is electrically connected to the capacitor cell through the penetration electrode.

5. The apparatus of claim 2, wherein at least one of the penetration electrode and the capacitor cell comprises a barrier metal layer.

6. The apparatus of claim 1, wherein the second substrate comprises:
a transistor layer, wherein the transistor layer comprises at least one transistor formed on a semiconductor substrate; and
at least one metal layer, wherein said at least one metal layer is formed over the transistor layer.

7. The apparatus of claim 1, wherein the capacitor cell comprises:
a bottom electrode;
an insulation layer; and
a top electrode.

8. The apparatus of claim 7, wherein at least one of the bottom electrode and the top electrode comprise at least one of W, Cu, Al, Au, and Au.

9. The apparatus of claim 1, wherein the second substrate comprises:
a transistor layer comprising said at least one transistor; and
at least one wiring layer comprising at least one wire.

10. The apparatus of claim 9, wherein said at least one wiring layer comprises three wiring layers.

11. A method comprising:
forming a first substrate comprising a capacitor cell;
forming a second substrate comprising a circuit unit, wherein the circuit unit comprises at least one transistor and at least one wire; and
electrically connecting the capacitor cell and the circuit unit with a connection electrode.

12. The method of claim 11, comprising forming a penetration electrode through the first substrate, wherein the penetration electrode is connected to the capacitor cell, and wherein the penetration electrode penetrates the semiconductor substrate.

13. The method of claim 12, wherein the penetration electrode comprises at least one of W, Cu, Al, Au, and Au.

14. The method of claim 12, wherein the connection electrode is electrically connected to the capacitor cell through the penetration electrode.

15. The method of claim 12, wherein at least one of the penetration electrode and the capacitor cell comprises a barrier metal layer.

16. The method of claim 11, comprising:
forming a transistor layer in the second substrate, wherein the transistor layer comprises said at least one transistor formed on a semiconductor substrate; and
forming at least one metal layer over the transistor layer, wherein said at least one metal layer comprises said at least one wire.

17. The method of claim 11, wherein the capacitor cell comprises:
a bottom electrode;
an insulation layer; and
a top electrode.

18. The method of claim 17, wherein at least one of the bottom electrode and the top electrode comprise at least one of W, Cu, Al, Au, and Au.

19. The method of claim 11, wherein the second substrate comprises:
a transistor layer comprising said at least one transistor; and
at least one wiring layer comprising said at least one wire.

20. The method of claim 19, wherein said at least one wiring layer comprises three wiring layers.
